(19) United States
(12) Patent Application Publication
(10) Pub. No.: US 2026/0123043 A1
(43) Pub. Date: Apr. 30, 2026

(54) ROBUST TOP-TO-BOTTOM GATE CONNECTIONS IN SEQUENTIAL STACKING

(71) Applicant: International Business Machines Corporation, Armonk, NY (US)

(72) Inventors: Chen Zhang, Santa Clara, CA (US); Shay Reboh, Guilderland, NY (US); Ruilong Xie, Niskayuna, NY (US); Tenko Yamashita, Schenectady, NY (US)

(21) Appl. No.: 18/926,293

(22) Filed: Oct. 24, 2024

(51) Int. Cl. H01L 27/092; H01L 21/822; H01L 21/8238; H01L 23/535; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 84/0186; H10D 84/038; H10D 88/01; H10W 20/20

(57) ABSTRACT

A stacked field effect transistor structure includes a lower field effect transistor including a lower first drain-source region, a lower second drain-source region, at least one lower channel region interconnecting the lower first and lower second drain-source regions, and a lower gate structure adjacent the at least one lower channel region. An upper field effect transistor includes an upper first drain-source region, an upper second drain-source region, and at least one upper channel region interconnecting the upper first and upper second drain-source regions, and an upper gate structure adjacent the at least one upper channel region. A gate interconnect connects the lower gate structure to the upper gate structure. The gate interconnect includes: a gate contact directly connected to the lower gate structure; and a contact plug directly connected to the top gate structure and electrically coupled to the gate contact.

### BACKGROUND

The present invention relates generally to the electrical, electronic, and computer arts, and, more particularly, to semiconductor devices including stacked field effect transistors (FETs).

Sequential stacking is a promising architecture for continued complementary metal oxide semiconductor (CMOS) scaling. A pertinent challenge in the sequential stacking process is how to form an electrical connection between the top gate and the corresponding bottom gate.

Vertical and lateral plugs have been proposed. In the former (vertical plug) approach, after the top gate high-k deposition, vertical reactive ion etching (RIE) is used to penetrate the bonding dielectric to reach the bottom gate, followed by top gate metal deposition. This has the following drawbacks: RIE happens very close to the channel, with a concomitant risk of channel damage; and if there is misalignment between the top gate and the bottom gate, the connection can be highly resistive. In the latter (lateral plug) approach, after a full height (top-to-bottom) gate cut, the bonding oxide is recessed, and a lateral metal plug is formed to connect the top and bottom gates. This approach still has the drawback that, if there is misalignment between the top gate and the bottom gate, the connection can be highly resistive.

### BRIEF SUMMARY

Principles of the invention provide techniques for robust top-to-bottom gate connections in sequential stacking. In one aspect, an exemplary stacked field effect transistor structure includes: a lower field effect transistor including a lower first drain-source region, a lower second drain-source region, at least one lower channel region interconnecting the lower first and lower second drain-source regions, and a lower gate structure adjacent the at least one lower channel region; an upper field effect transistor including an upper first drain-source region, an upper second drain-source region, and at least one upper channel region interconnecting the upper first and upper second drain-source regions, and an upper gate structure adjacent the at least one upper channel region; and a gate interconnect that connects the lower gate structure to the upper gate structure. The gate interconnect includes: a gate contact directly connected to the lower gate structure; and a contact plug directly connected to the top gate structure and electrically coupled to the gate contact.

In another aspect, a stacked field effect transistor array includes a plurality of stacked field effect transistor structures as just described; and at least one wiring structure with a plurality of horizontal wires and a plurality of vertical contacts selectively connected to at least a subset of the interconnected upper and lower gate structures and at least a subset of: the lower first drain-source regions, the lower second drain-source regions, the upper first drain-source regions and the upper second drain-source regions. In the array, all upper and lower gates structures are not necessarily interconnected.

In still another aspect, an exemplary method of forming a stacked field effect transistor structure includes: providing an array of lower field effect transistor initial structures, each including: a lower first drain-source region, a lower second drain-source region, at least one lower channel region interconnecting the lower first and lower second drain-source regions, a lower gate structure adjacent the at least one lower channel region, and a common inter-layer dielectric (ILD), the lower gate structures and the common inter-layer dielectric (ILD) cooperatively forming a planar outer surface. Further steps include forming lower gate contacts and additional insulator material outward of the planar outer surface, the lower gate contacts being in contact with at least some of the lower gate structures; forming an array of upper device precursor structures outward of the lower gate contacts and the additional insulator material, the upper device precursor structures each including at least one upper channel region and upper field effect transistor dummy gates that are bonded to the lower gate contacts and the additional insulator material using bonding dielectric; recessing the bonding dielectric to form bonding dielectric portions at least over the lower gate contacts; directionally depositing a material that is etch-resistant compared to the bonding dielectric portions over outer surfaces of: the upper device precursor structures, the lower gate contacts, and the additional insulator material; epitaxially forming upper first and upper second drain-source regions on either side of the upper channel regions, filling with upper inter-layer dielectric (ILD), and planarizing; carrying out replacement metal gate formation to replace the upper field effect transistor dummy gates with an upper gate structure adjacent the upper channel regions; forming gate cuts; laterally recessing the bonding dielectric portions remaining after the forming the gate cuts to form a contact-plug formation region; and carrying out conformal deposition and etch back to form contact plugs in the contact-plug formation region, the contact plugs being directly connected to the upper gate structures and electrically coupled to the lower gate contacts.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
techniques to form robust top-to-bottom gate connections in sequential stacking;
design flexibility in terms of where to put the top and bottom gate connections, providing design flexibility such that some gates can be connected and some not.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a top view of a starting structure in accordance with an aspect of the invention, also generally representative of intermediate structures and a final structure;

FIGS. 2A, 2B, and 2C are views of the starting structure along lines A-A, B-B, and C-C in FIG. 1 respectively, according to aspects of the invention;

FIGS. 3A-12C show subsequent manufacturing steps wherein “A,” “B,” and “C” views are along lines A-A, B-B, and C-C in FIG. 1 respectively, according to aspects of the invention;

FIG. 13 is a view, similar to FIG. 12A, of an alternative embodiment, according to aspects of the invention; and

FIG. 14 depicts a stacked field effect transistor array, in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, some prior art techniques employ vertical RIE to penetrate the dielectric to reach the bottom gate, followed by top gate metal deposition, which can have several drawbacks. Advantageously, one or more embodiments overcome the drawbacks of the prior art by employing a two-component connection between the top gate and the bottom gate. The bottom component can have a wider width than the gate length. The top component can be a lateral via.

Indeed, in one or more embodiments, form a wide bottom gate contact to mitigate the impact of top gate misalignment on connection resistance. Furthermore, in one or more embodiments, a lateral metal plug is employed to connect the top gate with the bottom gate contact.

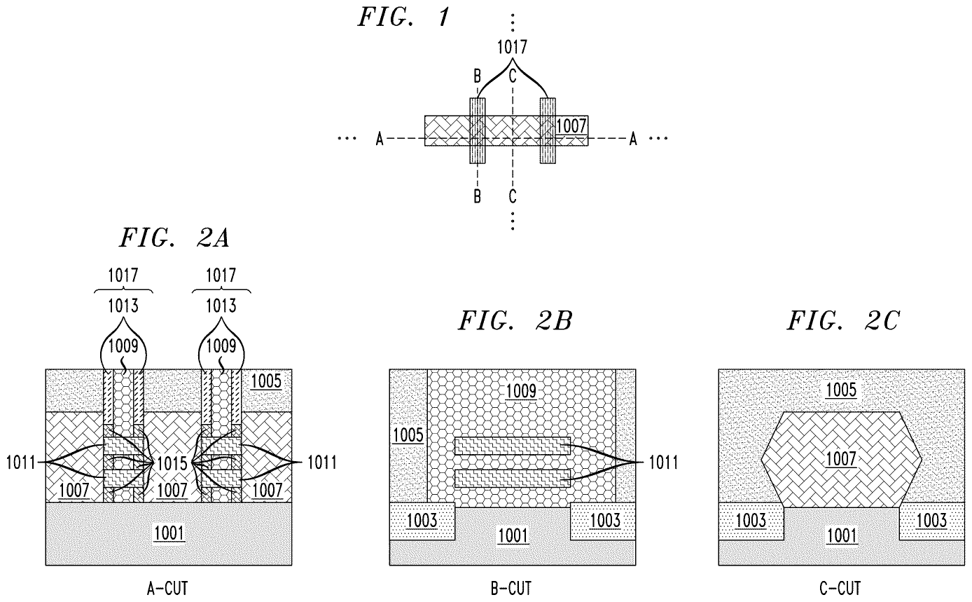

Now consider an exemplary process flow. Refer initially to the top view in FIG. 1 and the views along lines A-A, B-B, and C-C in FIG. 1 which are respectively presented in FIGS. 2A, 2B, and 2C—depicted is a bottom field effect transistor (FET) that can be formed using techniques familiar to the skilled artisan. Note the substrate 1001, shallow trench isolation (STI) 1003, inter-layer dielectric (ILD) 1005, epitaxially grown source-drain (S-D) regions 1007, bottom gate stack 1009, silicon channels 1011, inner spacers 1015, and outer spacers 1013. The gate stacks (e.g., HKMG) plus the spacers 1013, 1015 are designated as 1017.

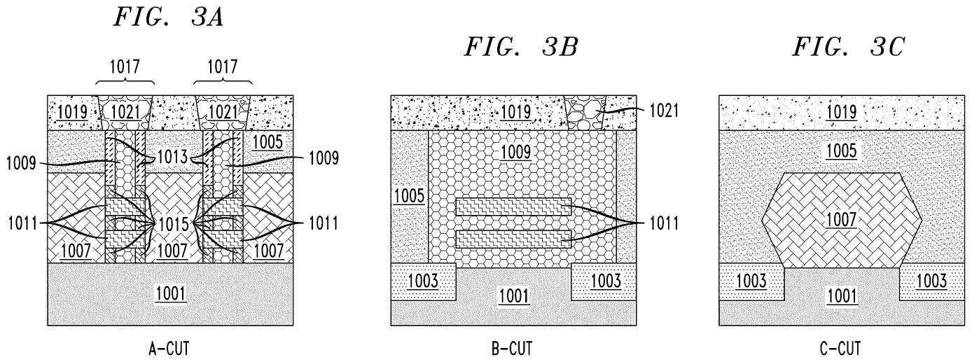

FIGS. 3A, 3B, and 3C correspond to FIGS. 2A, 2B, and 2C after the formation of bottom gate contacts 1021. Note the additional insulator material 1019. Note also that the contacts can be wider than the gate width as discussed elsewhere herein. Conventional lithography, etching, and metallization can be employed.

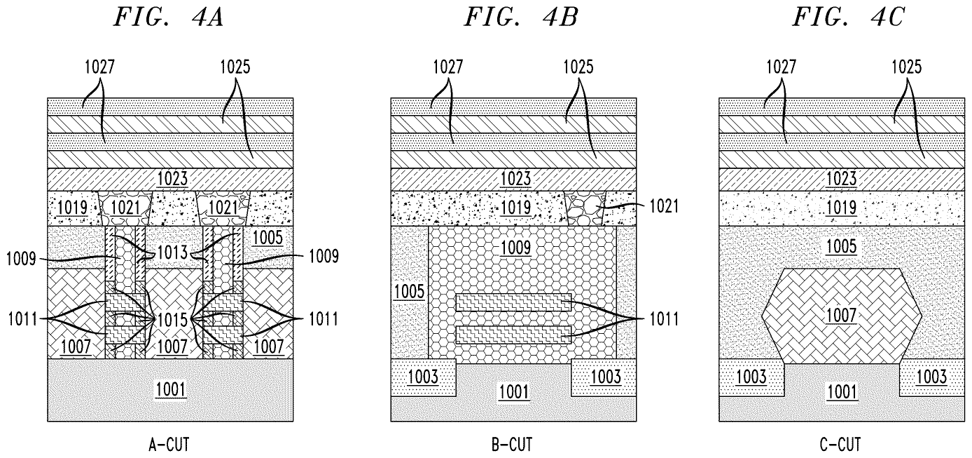

FIGS. 4A, 4B, and 4C correspond to FIGS. 3A, 3B, and 3C after bonding on new layers of nanosheets to form the top FET. Note the bonding dielectric 1023 and alternating layers of SiGe 1025 and Si 1027. The steps depicted in FIGS. 4A-4C can be carried out with conventional techniques—the skilled artisan will be familiar with FINFET (fin-type field effect transistors) nanosheets and stacked FET bonding.

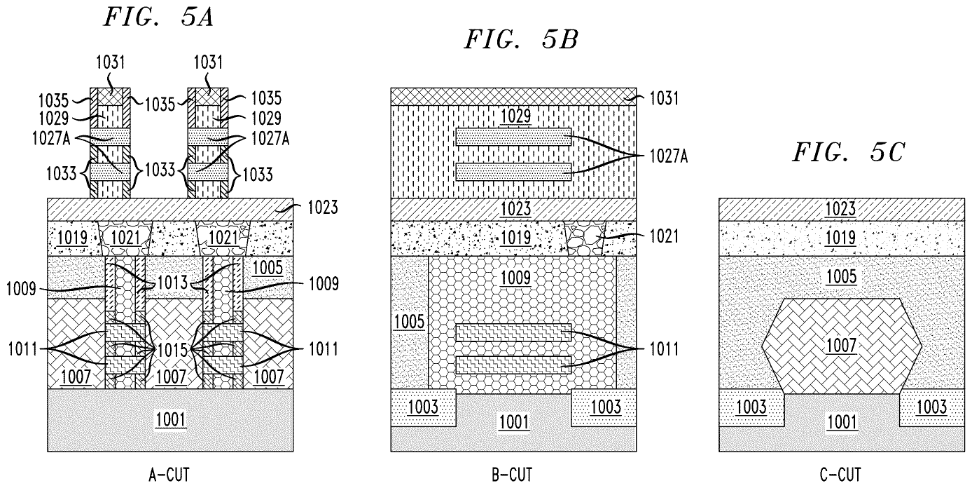

FIGS. 5A, 5B, and 5C correspond to FIGS. 4A, 4B, and 4C after forming the top FET dummy gate 1029 (e.g., amorphous silicon (s-Si)) and spacers (inner spacers 1033 and outer spacers 1035). Note also the gate cap 1031 (e.g., SiN). The skilled artisan will be familiar with selective etching of SiGe with respect to Si and other known techniques to implement the operations in FIGS. 5A, 5B, and 5C. Note the channels 1027A after etching.

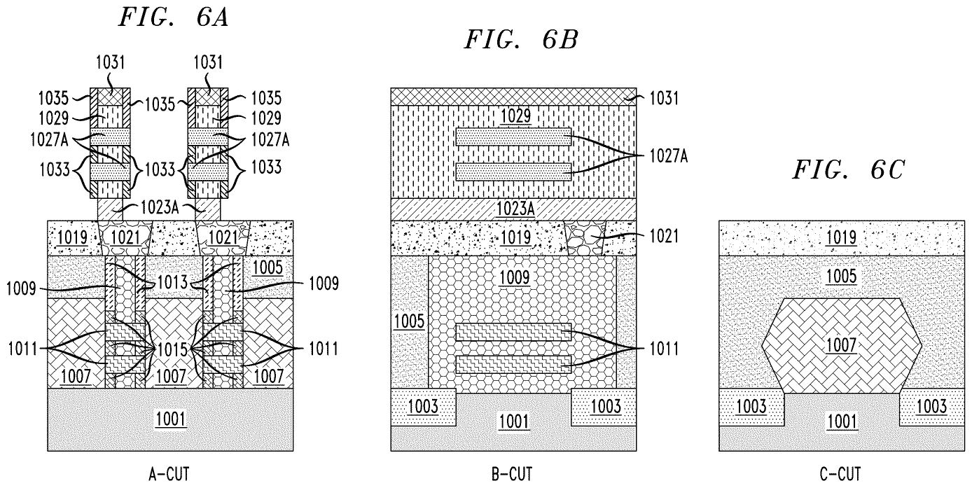

FIGS. 6A, 6B, and 6C correspond to FIGS. 5A, 5B, and 5C after recessing the bonding dielectric. The recessed dielectric is designated as 1023A. The steps depicted in FIGS. 6A-6C can be carried out with conventional techniques.

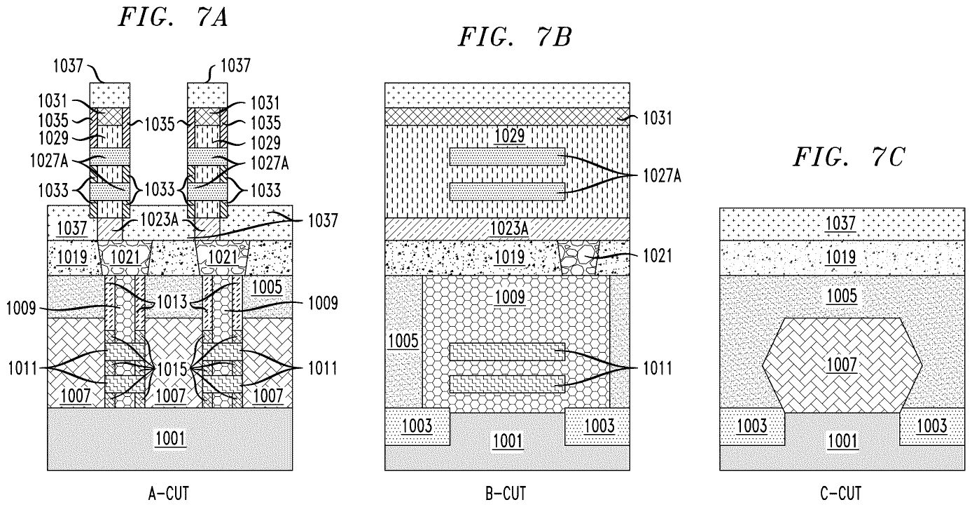

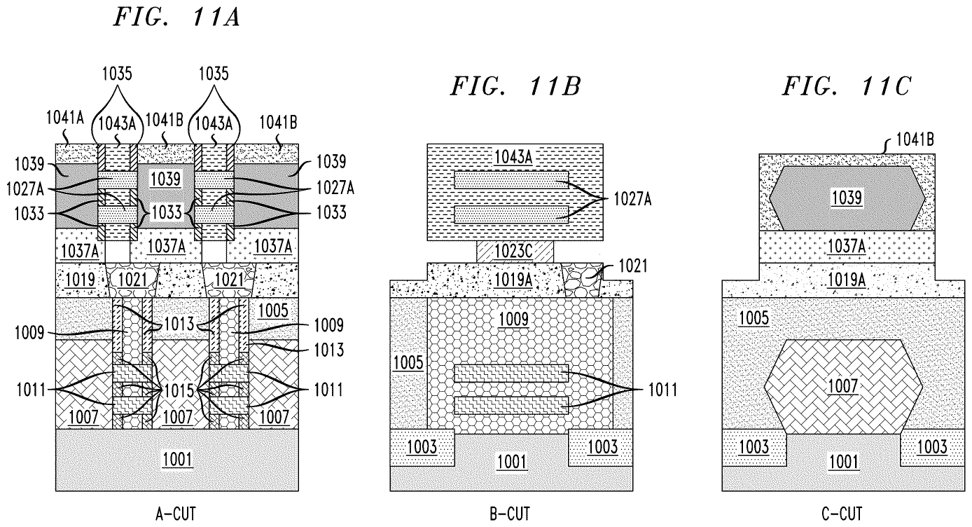

FIGS. 7A, 7B, and 7C correspond to FIGS. 6A, 6B, and 6C after directional deposition of a material that has etch selectivity with respect to bonding dielectric 1023, such as a SiN-based material 1037. The steps depicted in FIGS. 7A-7C can be carried out with conventional techniques. The SiN-based material can include SiN, SiBCN SiOCN, and the like. FIGS. 11A-11C show etch selectivity where material 1037 stays relatively intact compared to remaining bonding dielectric 1023B (discussed below).

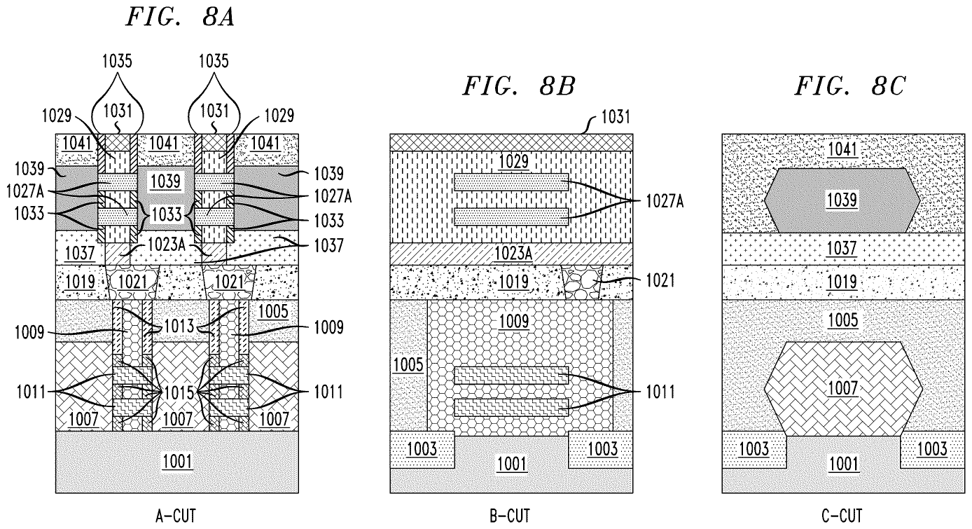

FIGS. 8A, 8B, and 8C correspond to FIGS. 7A, 7B, and 7C after forming top epitaxial source-drain regions 1039, filling with upper ILD 1041, and carrying out chemical-mechanical planarization (CMP), using known techniques.

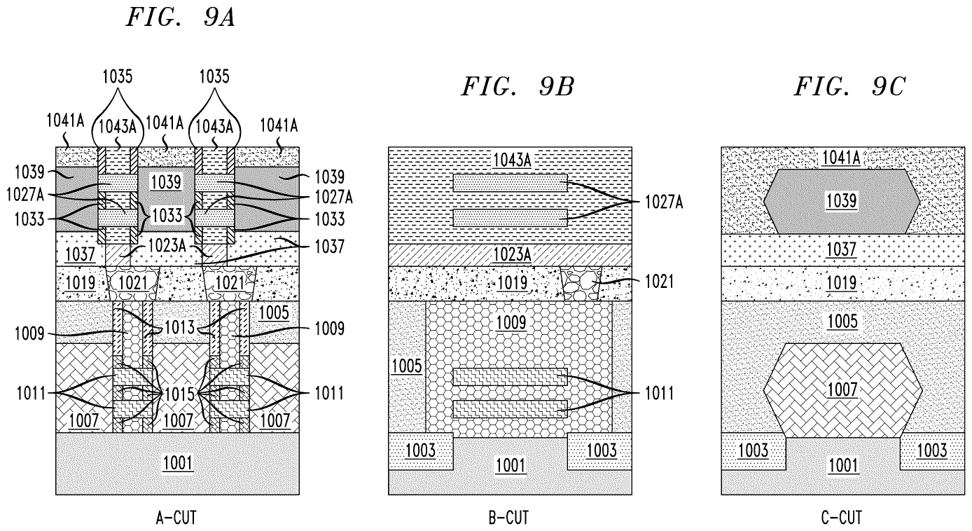

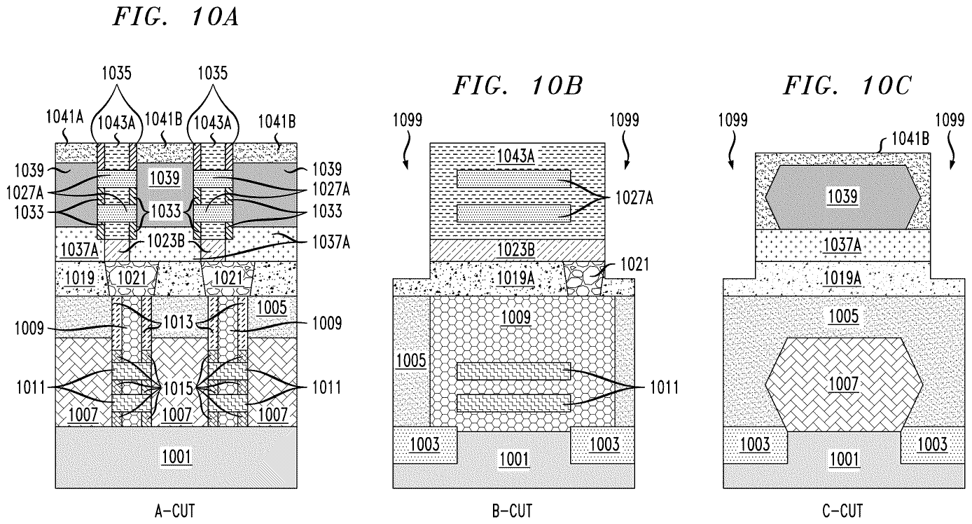

FIGS. 9A, 9B, and 9C correspond to FIGS. 8A, 8B, and 8C after forming the top gate stack 1043 (e.g., using the replacement metal gate process). The gate cap 1031 is removed and the upper ILD 1041 is thinned and now designated as 1041A. The skilled artisan will be familiar with gate formation such as high-K metal gates (HKMG) formed using the replacement process. Such gates include a high-K (e.g., hafnium-based) dielectric and metal portions such as TiN, TiAlN, TiSiN, TaN, TaAlN, TaSiN, and the like. For illustrative convenience, the gate stacks are shown in unitary form in the drawings, but the skilled artisan will appreciate that they include both high-K dielectric and metal in a known manner. It will be appreciated that the gate-to-gate connectors are between the metal portions of the gate stacks.

FIGS. 10A, 10B, and 10C correspond to FIGS. 9A, 9B, and 9C after the top gate cut process—note the gate cuts 1099. Insulator material 1019 is designated as 1019A after the cutting process; SiN-based material 1037 is designated as 1037A after the cutting process; thinned ILD 1041A is designated as 1041B after the cutting process; recessed dielectric 1023A is designated as 1023B after the cutting process; and top gate stack 1043 is designated as top gate 1043A after the cutting process.

FIGS. 11A, 11B, and 11C correspond to FIGS. 10A, 10B, and 10C after selective lateral recess of remaining bonding dielectric 1023B; the laterally recessed bonding dielectric is designated as 1023C.

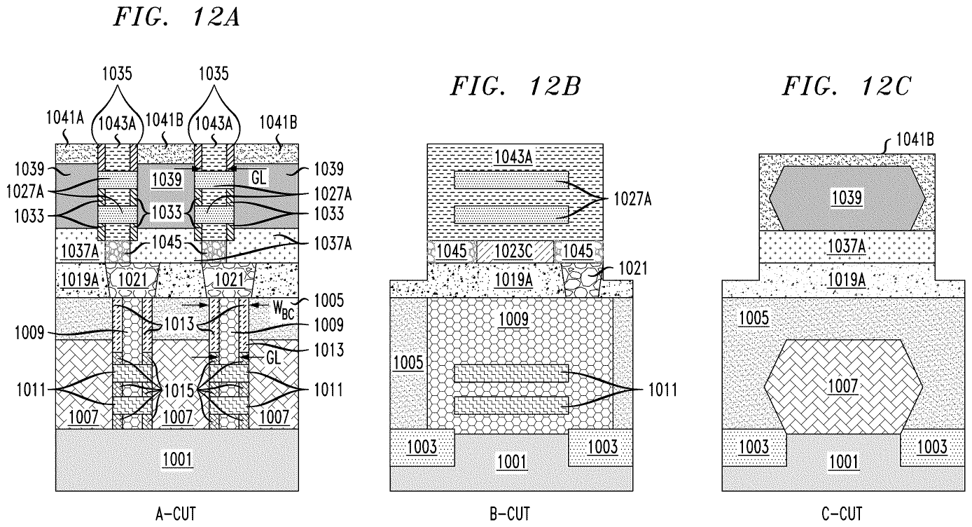

FIGS. 12A, 12B, and 12C correspond to FIGS. 11A, 11B, and 11C after forming the lateral metal connectors (lateral metal plugs 1045) by conformal deposition and etch-back.

Thus, it will be appreciated that, as discussed above, one or more embodiments employ a two-component connection between the top gate (e.g., metal portion of top gate 1043A) and the bottom gate (e.g., metal portion of bottom gate stack 1009). The bottom component (bottom gate contact 1021) can have a wider width W_{BC} than the gate length GL. The width W_{BC} is taken in the example as the bottom edge of the trapezoidal shape of bottom component (bottom gate contact 1021); the trapezoidal shape reflects the etching process. In a non-limiting example, the gate length GL is the same for both the top and bottom FETs within process tolerances—the gate length GL is just the width of elements 1009/1043A without the spacers. The top component can be a lateral via (lateral metal plug 1045). In one or more embodiments, form a wide bottom gate contact 1021 to mitigate the impact of top gate misalignment on connection resistance, where a lateral metal plug 1045 is employed to connect the top gate (e.g., metal portion of top gate 1043A) with the bottom gate contact 1021.

One or more embodiments accordingly provide a stacked transistor structure including a top gate stacked above a bottom gate (bottom gate stack 1009); and a gate interconnect that connects the top gate to the bottom gate, where the gate interconnect includes a (bottom) gate contact 1021 directly connected to the bottom gate and a contact plug (lateral metal plug 1045) directly connected to the top gate.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary stacked field effect transistor structure includes a lower field effect transistor including a lower first drain-source region 1007, a lower second drain-source region 1007, and at least one lower channel region (e.g., of the silicon channels 1011) interconnecting the lower first and lower second drain-source regions. Also included in the lower field effect transistor is a lower gate structure (bottom gate stack 1009) adjacent the at least one lower channel region (“adjacent” means a relationship with the at least one channel region so as to create channel when the gate structure is energized). Also included in the stacked field effect transistor structure is an upper field effect transistor including an upper first drain-source region 1039, an upper second drain-source region 1039, at least one upper channel region (e.g., of the channels 1027A) interconnecting the upper first and upper second drain-source regions, and an upper gate structure (top gate 1043A) adjacent the at least one upper channel region. A gate interconnect connects the lower gate structure to the upper gate structure, and includes: a (bottom) gate contact 1021 directly connected to the lower gate structure; and a contact plug (lateral metal plug 1045) directly connected to the top gate structure and electrically coupled to the (bottom) gate contact 1021.

In one or more embodiments, the contact plug includes a lateral metal via.

In one or more embodiments, a width W_{GC} of the gate contact is greater than a gate length GL of the lower gate structure and the upper gate structure.

The lower gate structure and the upper gate structure may be misaligned in some cases within process tolerances (i.e., not deliberate misalignment, but such mis-alignment can advantageously be tolerated).

In one or more embodiments, the lower and upper field effect transistors are complementary; e.g., PFET/NFET, NFET/PFET, NFET/NFET, PFET/PFET.

In some cases, the at least one lower channel region includes a plurality of lower nanosheets and the lower gate structure at least partially surrounds the plurality of lower nanosheets (optionally, gate all around or GAA); and the at least one upper channel region includes a plurality of upper nanosheets and the upper gate structure at least partially surrounds the plurality of upper nanosheets (optionally, gate all around or GAA).

One or more embodiments further include first and second insulating regions between the lower and upper field effect transistors, and the gate contact is located in the lower insulating region and the contact plug is located in the upper insulating region. For example, the lower insulating region includes inter-layer dielectric (ILD) 1005 and additional insulator material 1019A, and the gate contact is located in the additional insulator material 1019A; and the upper insulating region includes recessed bonding dielectric 1023C and a material 1037A that is etch-resistant compared to the recessed bonding dielectric. Optionally, the material 1037A that is etch-resistant compared to the recessed bonding dielectric is selected from the group consisting of SiN, SiBCN, and SiOCN.

In another aspect, an exemplary method of forming a stacked field effect transistor structure includes providing an array of lower field effect transistor initial structures (see FIG. 1, array indicated be ellipses, and FIGS. 2A-2C). Each stacked field effect transistor structure includes a lower first drain-source region 1007, a lower second drain-source region 1007, at least one lower channel region (e.g., of the silicon channels 1011) interconnecting the lower first and lower second drain-source regions, and a lower gate structure (bottom gate stack 1009) adjacent the at least one lower channel region. A common inter-layer dielectric (ILD) 1005 is provided, and the lower gate structures and the common inter-layer dielectric (ILD) cooperatively form a planar outer surface.

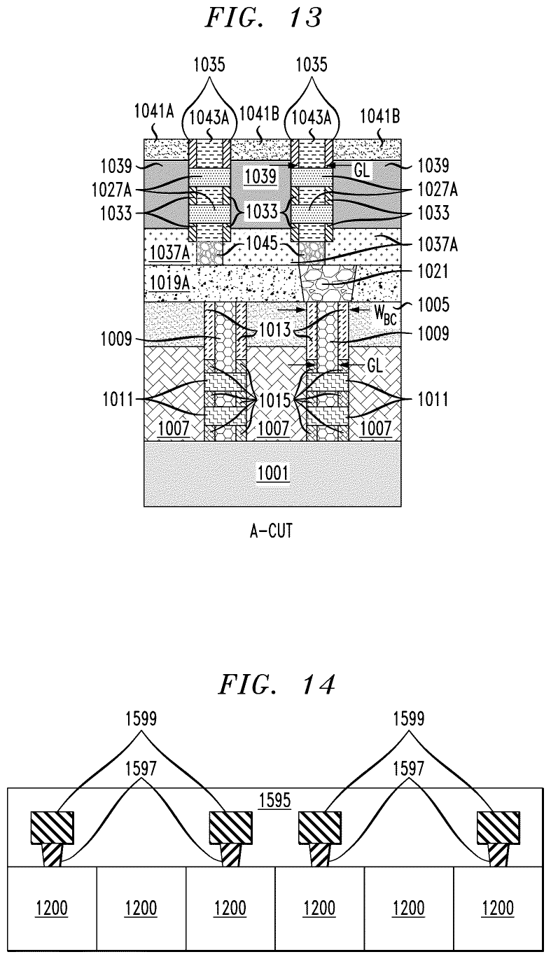

Referring to FIGS. 3A and 3C, a further step includes forming lower (bottom) gate contacts 1021 and additional insulator material 1019 outward of the planar outer surface. The lower gate contacts are in contact with at least some of the lower gate structures. Note that, as, for example, in FIG. 13, there is not necessarily a lower gate contact for each lower gate structure.

Referring, for example, to FIGS. 4A-5C, a still further step includes forming an array of upper device precursor structures outward of the lower (bottom) gate contacts 1021 and the additional insulator material 1019. The upper device precursor structures each include at least one upper channel region and upper field effect transistor dummy gates that are bonded to the lower (bottom) gate contacts 1021 and the additional insulator material 1019 using bonding dielectric 1023. The dummy gates do not necessarily exist at the time of the bonding, as per the steps in FIGS. 4A-5C.

Further steps include, as per FIGS. 6A-6C, recessing the bonding dielectric to form bonding dielectric portions (recessed dielectric 1023A) at least over the lower gate contacts; as per FIGS. 7A-7C, directionally depositing a material 1037 that is etch-resistant compared to the bonding dielectric portions over outer surfaces of: the upper device precursor structures, the lower gate contacts, and the additional insulator material; and, as per FIGS. 8A-8C, epitaxially forming upper first and upper second drain-source regions on either side of the upper channel regions, filling with upper inter-layer dielectric (ILD) 1041, and planarizing.

Still further steps include, as per FIGS. 9A-9C, carrying out replacement metal gate formation to replace the upper field effect transistor dummy gates with an upper gate structure (top gate 1043A) adjacent the upper channel regions; as per FIGS. 10A-10C, forming gate cuts 1099; as per GIGS. 11A-11C, laterally recessing the bonding dielectric portions (recessed dielectric 1023A) remaining after the forming the gate cuts to form a contact-plug formation region; and, as per FIGS. 12A-12C, carrying out conformal deposition and etch back to form contact plugs (lateral metal plugs 1045) in the contact-plug formation region, the contact plugs (lateral metal plugs 1045) being directly connected to the upper gate structures (top gates 1043A) and electrically coupled to the lower (bottom) gate contacts 1021.

Referring, for example, to FIGS. 4A-5C, the step of forming the array of upper device precursor structures outward of the lower (bottom) gate contacts 1021 and the additional insulator material 1019 could include, for example, bonding alternating layers of nanosheets 1027 and sacrificial material (e.g., SiGe 1025) outward of the lower (bottom) gate contact 1021 and the additional insulator material 1019 using bonding dielectric 1023 (FIGS. 4A-4C); and forming an upper field effect transistor dummy gate and spacers outward of the bonding dielectric 1023, where the upper field effect transistor dummy gate at least partially surrounds at least one upper channel region formed from the nanosheet (FIGS. 5A-5C).

In one or more embodiments, in the step of forming the lower gate contacts, a width of the gate contacts is greater than a gate length of the lower gate structure.

In another aspect, referring to FIG. 14, a stacked field effect transistor array includes a plurality of stacked field effect transistor structures as just described, numbered as 1200, and at least one wiring structure with a plurality of horizontal wires 1599 and a plurality of vertical contacts 1597 selectively connected to at least a subset of the coupled upper and lower gate structures and at least a subset of: the lower first drain-source regions, the lower second drain-source regions, the upper first drain-source regions and the upper second drain-source regions. The horizontal wires 1599 and vertical contacts 1597 are shown at a high level of generality. Any desired elements can be in the array—inverters, ring oscillators, static random-access memory (SRAM) and the like—anything with FETs as a fundamental unit. Known materials can be used to form standard interconnects. There can be multiple wiring layers in the wiring structure and the wires and contacts can be in a dielectric 1595. Also, referring to FIG. 13, it can be that only a subset of the plurality of stacked field effect transistor structures have the gate interconnect portion (bottom gate contact 1021)—in some cases, one FET is over another FET, but their gates are not coupled.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of exemplary sequentially stacked FET structure(s) with robust top-to-bottom gate connections as disclosed herein.

An integrated circuit in accordance with aspects of the present inventions can be employed in essentially any application and/or electronic system where one or more aspects of the exemplary sequentially stacked FET structure(s) with robust top-to-bottom gate connections as disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A stacked field effect transistor structure comprising:
a lower field effect transistor comprising a lower first drain-source region, a lower second drain-source region, at least one lower channel region interconnecting the lower first and lower second drain-source regions, and a lower gate structure adjacent the at least one lower channel region;
an upper field effect transistor comprising an upper first drain-source region, an upper second drain-source region, and at least one upper channel region interconnecting the upper first and upper second drain-source regions, and an upper gate structure adjacent the at least one upper channel region; and
a gate interconnect that connects the lower gate structure to the upper gate structure, where the gate interconnect includes:
a gate contact directly connected to the lower gate structure; and
a contact plug directly connected to the upper gate structure and electrically coupled to the gate contact.

2. The stacked field effect transistor structure of claim 1, wherein the contact plug comprises a lateral metal via.

3. The stacked field effect transistor structure of claim 2, wherein a width of the gate contact is greater than a gate length of the lower gate structure and the upper gate structure.

4. The stacked field effect transistor structure of claim 3, wherein the lower gate structure and the upper gate structure are misaligned within process tolerances.

5. The stacked field effect transistor structure of claim 3, wherein the lower and upper field effect transistors are complementary.

6. The stacked field effect transistor structure of claim 3, wherein:
the at least one lower channel region comprises a plurality of lower nanosheets and the lower gate structure at least partially surrounds the plurality of lower nanosheets; and
the at least one upper channel region comprises a plurality of upper nanosheets and the upper gate structure at least partially surrounds the plurality of upper nanosheets.

7. The stacked field effect transistor structure of claim 3, further comprising first and second insulating regions between the lower and upper field effect transistors, wherein the gate contact is located in the lower insulating region and the contact plug is located in the upper insulating region.

8. The stacked field effect transistor structure of claim 7, wherein:
the lower insulating region includes inter-layer dielectric (ILD) and additional insulator material, and the gate contact is located in the additional insulator material; and
the upper insulating region includes recessed bonding dielectric and a material that is etch-resistant compared to the recessed bonding dielectric.

9. The stacked field effect transistor structure of claim 8, wherein the material that is etch-resistant compared to the recessed bonding dielectric is selected from the group consisting of SiN, SiBCN, and SiOCN.

10. A method of forming a stacked field effect transistor structure, the method comprising:
providing an array of lower field effect transistor initial structures, each comprising:
a lower first drain-source region,
a lower second drain-source region,
at least one lower channel region interconnecting the lower first and lower second drain-source regions,
a lower gate structure adjacent the at least one lower channel region, and
a common inter-layer dielectric (ILD), the lower gate structures and the common inter-layer dielectric (ILD) cooperatively forming a planar outer surface;
forming lower gate contacts and additional insulator material outward of the planar outer surface, the lower gate contacts being in contact with at least some of the lower gate structures;
forming an array of upper device precursor structures outward of the lower gate contacts and the additional insulator material, the upper device precursor structures each including at least one upper channel region and upper field effect transistor dummy gates that are bonded to the lower gate contacts and the additional insulator material using bonding dielectric;
recessing the bonding dielectric to form bonding dielectric portions at least over the lower gate contacts;
directionally depositing a material that is etch-resistant compared to the bonding dielectric portions over outer surfaces of: the upper device precursor structures, the lower gate contacts, and the additional insulator material;
epitaxially forming upper first and upper second drain-source regions on either side of the upper channel regions, filling with upper inter-layer dielectric (ILD), and planarizing;
carrying out replacement metal gate formation to replace the upper field effect transistor dummy gates with an upper gate structure adjacent the upper channel regions;
forming gate cuts;
laterally recessing the bonding dielectric portions remaining after the forming the gate cuts to form a contact-plug formation region; and
carrying out conformal deposition and etch back to form contact plugs in the contact-plug formation region, the contact plugs being directly connected to the upper gate structures and electrically coupled to the lower gate contacts.

11. The method of claim 10, wherein, in the step of forming the lower gate contacts, a width of the gate contacts is greater than a gate length of the lower gate structure.

12. A stacked field effect transistor array comprising:
a plurality of stacked field effect transistor structures comprising:
a lower field effect transistor comprising a lower first drain-source region, a lower second drain-source region, at least one lower channel region interconnecting the lower first and lower second drain-source regions, and a lower gate structure adjacent the at least one lower channel region;
an upper field effect transistor comprising an upper first drain-source region, an upper second drain-source region, and at least one upper channel region interconnecting the upper first and upper second drain-source regions, and an upper gate structure adjacent the at least one upper channel region; and
for at least a subset of the plurality of stacked field effect transistor structures, a gate interconnect that connects the lower gate structure to the upper gate structure, where the gate interconnect includes:
a gate contact directly connected to the lower gate structure; and
a contact plug directly connected to the top gate structure and electrically coupled to the gate contact; and
at least one wiring structure with a plurality of horizontal wires and a plurality of vertical contacts selectively connected to at least a subset of the interconnected upper and lower gate structures and at least a subset of:
the lower first drain-source regions, the lower second drain-source regions, the upper first drain-source regions and the upper second drain-source regions.

13. The stacked field effect transistor array of claim 12, wherein the contact plugs comprise lateral metal vias.

14. The stacked field effect transistor array of claim 13, wherein a width of the gate contacts is greater than a gate length of the lower gate structures and the upper gate structures.

15. The stacked field effect transistor array of claim 14, wherein the lower gate structures and the upper gate structures are misaligned within process tolerances.

16. The stacked field effect transistor array of claim 14, wherein the lower and upper field effect transistors are complementary.

17. The stacked field effect transistor array of claim 14, wherein:
for each of the lower field effect transistors, the at least one lower channel region comprises a plurality of lower nanosheets and the lower gate structure at least partially surrounds the plurality of lower nanosheets; and
for each of the upper field effect transistors, the at least one upper channel region comprises a plurality of upper nanosheets and the upper gate structure at least partially surrounds the plurality of upper nanosheets.

18. The stacked field effect transistor array of claim 14, further comprising first and second insulating regions between the lower and upper field effect transistors, wherein the gate contacts are located in the lower insulating region and the contact plugs are located in the upper insulating region.

19. The stacked field effect transistor array of claim 18, wherein:
the lower insulating region includes inter-layer dielectric (ILD) and additional insulator material, and the gate contacts are located in the additional insulator material; and
the upper insulating region includes recessed bonding dielectric and a material that is etch-resistant compared to the recessed bonding dielectric.

20. The stacked field effect transistor array of claim 19, wherein the material that is etch-resistant compared to the recessed bonding dielectric is selected from the group consisting of SiN, SiBCN, and SiOCN.
